(19) United States
(12) Patent Application Publication
(10) Pub. No.: US 2026/0362694 A1
(43) Pub. Date: Nov. 12, 2026

(54) MEMORY DEVICE AND METHOD OF MANUFACTURING THE MEMORY DEVICE

(71) Applicant: SK hynix Inc., Icheon-si Gyeonggi-do (KR)

(72) Inventors: Na Yeong YANG, Icheon-si Gyeonggi-do (KR); Rho Gyu KWAK, Icheon-si Gyeonggi-do (KR); Mi Seong PARK, Icheon-si Gyeonggi-do (KR); Jung Shik JANG, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 19/377,342

(22) Filed: Nov. 3, 2025

(30) Foreign Application Priority Data
May 9, 2025 (KR) 10-2025-0060545

(51) Int. Cl. H10B 43/27; G11C 16/04; H10B 43/10; H10B 43/35; H10D 30/69; H10B 43/40; H10D 30/01; H10W 90/00

(52) U.S. Cl. CPC H10B 43/27; G11C 16/0483; H10B 43/10; H10B 43/35; H10D 30/693; H10B 43/40; H10D 30/0413; H10W 90/792

(57) ABSTRACT

A memory device includes a stack including conductive layers alternately stacked with interlayer insulating layers in a first direction, a channel opening extending through the stack in the first direction. The memory device includes a first channel pattern spaced apart from a second channel pattern in a second direction perpendicular to the first direction, and extending in the channel opening in the first direction. The memory device includes first data storage patterns located between the first channel pattern and the conductive layers and spaced apart in the first direction, and second data storage patterns located between the second channel pattern and the conductive layers and spaced apart in the first direction. The first data storage patterns are spaced apart from the second data storage patterns in the second direction.

### CROSS REFERENCE TO RELATED APPLICATION

The present application claims priority under 35 U.S.C. §119(a) to Korean patent application number 10-2025-0060545 filed on May 9, 2025, in the Korean Intellectual Property Office, the entire contents of which application is incorporated herein by reference.

### BACKGROUND

### 1. Technical Field

The present disclosure generally relate to a memory device and a method of manufacturing the memory device, including but not limited to a memory device including memory blocks having a three-dimensional structure and a method of manufacturing the memory device including the memory blocks having a three-dimensional structure.

### 2. Related Art

A memory device may include a non-volatile memory device that retains stored data when the power supply is interrupted or discontinued. A non-volatile memory device may have a two-dimensional structure or a three-dimensional structure according to how memory cells are arranged. Memory cells of a non-volatile memory device having a two-dimensional structure are arranged in a single layer on a substrate, and memory cells of a non-volatile memory device having a three-dimensional structure are stacked in a vertical direction on the substrate. Because the integration density of a non-volatile memory device having a three-dimensional structure is higher than the integration density of a non-volatile memory device having a two-dimensional structure, electronic devices are more frequently manufactured with non-volatile memory devices having a three-dimensional structures. To further enhance the integration density of a non-volatile memory device having a three-dimensional structure, a memory device in which two or more cell strings are formed in one channel opening has been proposed, or to further enhance the reliability of a non-volatile memory device having a three-dimensional structure, a memory device including data storage patterns vertically spaced apart from each other has been proposed.

### SUMMARY

A memory device according to an embodiment of the present disclosure may include: a stack in which conductive layers are alternately stacked with interlayer insulating layers in a first direction, a channel opening extending through the stacked structure in the first direction; a first channel pattern spaced apart from a second channel pattern in a second direction perpendicular the first direction, the first channel pattern and the second channel pattern extending in the channel opening in the first direction; first data storage patterns located between the first channel pattern and the conductive layers and spaced apart in the first direction; and second data storage patterns located between the second channel pattern and the conductive layers and spaced apart in the first direction, wherein the first data storage patterns are spaced apart from the second data storage patterns in the second direction.

A method of manufacturing a memory device according to an embodiment of the present disclosure may include: forming a channel opening extending through a stack in a first direction; forming a plurality of first data storage patterns spaced apart in the first direction within the channel opening, a plurality of second data storage patterns spaced apart in the first direction within the channel opening, each of the plurality of first data storage patterns is spaced apart from a different one of the plurality of second data storage patterns spaced apart from each other in a second direction perpendicular to the first direction; forming a channel layer within the plurality of first data storage patterns and the plurality of second data storage patterns in the channel opening and extending in the first direction; and forming a first channel pattern spaced apart from a second channel pattern in the second direction by removing sections of the channel layer.

A memory device according to an embodiment of the present disclosure may include a stack including conductive layers alternately stacked with interlayer insulating layers in a first direction and a cell plug formed within a channel opening extending through the stack in the first direction. The cell plug may include a first channel pattern spaced apart from a second channel pattern in a second direction perpendicular to the first direction; the first data storage pattern located between consecutive protruding patterns in the first direction; and the second data storage pattern located between the consecutive protruding patterns in the first direction.

### BRIEF DESCRIPTION OF THE DRAWINGS

FIG. 1 is a diagram illustrating a memory device according to an embodiment of the present disclosure;

FIG. 2 is an isometric diagram illustrating a memory device according to an embodiment of the present disclosure;

FIG. 3 is a circuit diagram illustrating a connection configuration of a memory block according to an embodiment of the present disclosure;

FIGS. 4A-4C include a plan view and cross-sectional views illustrating a structure of a memory device according to an embodiment of the present disclosure;

FIGS. 5A and 5B are plan views illustrating a structure of a memory device according to an embodiment of the present disclosure;

FIGS. 6A-6O are cross-sectional diagrams of a memory device manufactured utilizing a method of manufacturing a memory device according to an embodiment of the present disclosure;

FIGS. 7A-7O are plan views of a memory device manufactured utilizing a method of manufacturing a memory device according to an embodiment of the present disclosure;

FIG. 8 is a cross-sectional diagram of a memory device according to an embodiment of the present disclosure;

FIG. 9 is a diagram illustrating a memory card system including a memory device according to an embodiment of the present disclosure; and

FIG. 10 is a block diagram illustrating a Solid-State Drive (SSD) system including a memory device according to an embodiment the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “vertical,” “horizontal,” “overlap,” “over,” “on,” “top,” “side,” “lower,” “higher,” “column,” “row,” “upside down,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas. The drawings are not necessarily drawn to scale, and complete versions of some structures are not shown between the cross-sectional views and corresponding plan views.

When one element is identified as “connected” or “coupled” to another element, the elements may be connected or coupled directly or through at least one intervening element between the elements. When two elements are identified as “directly connected” or “directly coupled,” one element is directly connected or directly coupled to the other element without an intervening element between the two elements.

Terms such as “first” and “second” are used to distinguish between various components and do not imply size, order, priority, quantity, or importance of the components. For example, a first component may be referred to as a second component in one example, and the second component may be referred to as a first component in another example.

To enhance the integration density of a non-volatile memory device having a three-dimensional structure, a memory device may include two or more cell strings formed in one channel opening. To enhance the reliability of a non-volatile memory device having a three-dimensional structure, a memory device may include vertically spaced apart data storage patterns. The present disclosure is directed to a memory device and a method of manufacturing the memory device capable of improving the integration density and reliability of the memory device and reducing the level of difficulty of a manufacturing process.

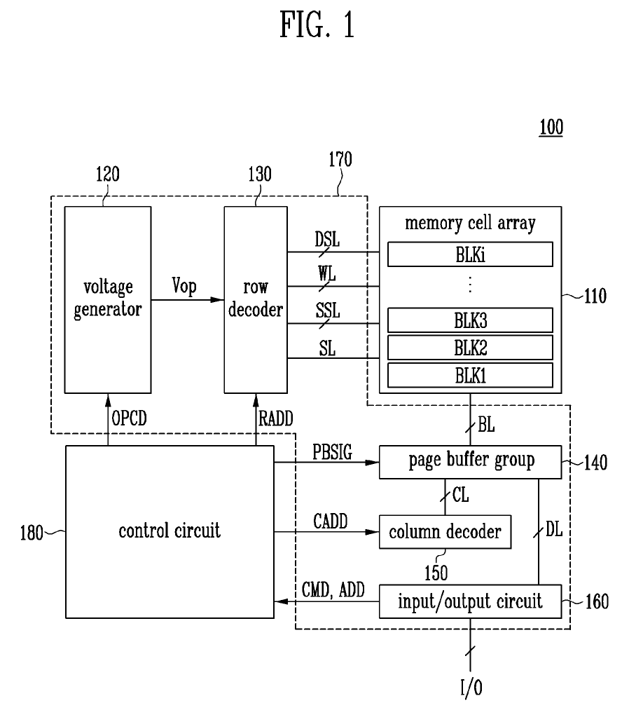

FIG. 1 is a diagram illustrating a memory device 100 according to an embodiment of the present disclosure.

Referring to FIG. 1, the memory device 100 includes a memory cell array 110, a peripheral circuit 170, and a control circuit 180.

The memory cell array 110 includes first memory blocks BLK1 to i-th memory block BLKi, where i is an integer greater than 1. Each of the first to i-th memory blocks BLK1 to BLKi includes memory cells that store data. Drain select lines DSL, word lines WL, source select lines SSL, and a source line SL are coupled to each of the memory blocks BLK1 to BLKi, and bit lines BL are coupled in common to the memory blocks BLK1 to BLKi.

The memory blocks BLK1 to BLKi have a three-dimensional structure. Memory blocks having a three-dimensional structure include memory cells stacked in a vertical or normal direction on a substrate. The memory cells are arranged in various ways in the memory blocks BLK1 to BLKi. For example, two or more cell strings may be arranged in a single channel opening extending through a stack. Compared to when a single cell string is arranged in a single channel opening, arranging two or more cell strings in a single channel opening increases the integration density of memory cells.

The memory cells stores one, two, or more bits of data according to how the memory cells are programmed. For example, a method in which one bit of data is stored in one memory cell is referred to as a single-level cell method, and a method in which two bits of data are stored is referred to as multi-level cell method. A method in which three bits of data are stored in one memory cell is referred to as a triple-level cell method, and a method in which four bits of data are stored is referred to as a quad-level cell method. Five or more bits of data may be stored in one memory cell.

The peripheral circuit 170 is configured to perform a program operation that stores data in the memory cell array 110, a read operation that outputs data stored in the memory cell array 110, and an erase operation that erases data stored in the memory cell array 110. The peripheral circuit 170 includes a voltage generator 120, a row decoder 130, a page buffer group 140, a column decoder 150, and an input/output circuit 160 in an embodiment.

The voltage generator 120 generates various operating voltages Vop used during the program operation, the read operation, and the erase operation in response to an operation code OPCD. For example, the voltage generator 120 is configured to generate program voltages, turn-on voltages, turn-off voltages, negative voltages, precharge voltages, verify voltages, read voltages, pass voltages, and erase voltages in response to the operation code OPCD. The operating voltages Vop generated at the voltage generator 120 are applied to the drain select lines DSL, the word lines WL, the source select lines SSL, and the source line SL of a selected memory block via the row decoder 130.

The program voltages are applied to a selected word line of the word lines WL in a program operation and are used to increase a threshold voltage of memory cells coupled to the selected word line. The turn-on voltages are applied to the drain select lines DSL or the source select lines SSL and are used to turn on drain select transistors or source select transistors. The turn-off voltages are applied to the drain select lines DSL or the source select lines SSL and are used to turn off the drain select transistors or the source select transistors. For example, the turn-off voltage may be 0 V. The precharge voltages are higher than 0 V and are applied to the bit lines during a read operation. The verify voltages are used during a verify operation to determine when a threshold voltage of selected memory cells reaches a target level. The verify voltages are at various levels depending on the target level and are applied to the selected word line.

The read voltages are applied to the selected word line during the read operation of the selected memory cells. For example, the read voltages are at various levels depending on the program method of the selected memory cells. The pass voltages are applied to unselected word lines of the word lines WL during the program or read operation, which are used to turn on memory cells coupled to the unselected word lines. The erase voltages are used during the erase operation to erase memory cells included in the selected memory block and are applied to the source line SL.

The row decoder 130 transfers, according to a row address RADD, the operating voltages Vop to the drain select lines DSL, the word lines WL, the source select lines SSL, and the source line SL coupled to the selected memory block. For example, the row decoder 130 is coupled to the voltage generator 120 via global lines and is coupled to the first to i-th memory blocks BLK1 to BLKi via the drain select lines DSL, the word lines WL, the source select lines SSL, and the source line SL.

The page buffer group 140 includes page buffers (not shown) coupled to the memory blocks BLK1 to BLKi, respectively. Each of the page buffers is coupled to one of memory blocks BLK1 to BLKi via the bit lines BL. During a read operation, the page buffers sense, in response to page buffer control signals PBSIG, a current or voltage of bit lines that varies according to the threshold voltage of the selected memory cells and stores the sensed data.

The column decoder 150 transfers data between the page buffer group 140 and the input/output circuit 160 in response to a column address CADD. For example, the column decoder 150 is coupled to the page buffer group 140 via column lines CL and transfers enable signals via the column lines CL. The page buffers included in the page buffer group 140 receive or output data via data lines DL in response to the enable signals.

The input/output circuit 160 receives or outputs a command CMD, an address ADD, and data via input/output lines I/O. For example, the input/output circuit 160 transfers the command CMD and the address ADD received from an external controller via the input/output lines I/O to the control circuit 180, and the input/output circuit 160 transfers the data received from the external controller via the input/output lines I/O to the page buffer group 140. Alternatively, the input/output circuit 160 outputs data received from the page buffer group 140 to the external controller through the input/output lines I/O.

In response to receiving the command CMD and the address ADD, the control circuit 180 outputs at least one of the operation code OPCD, the row address RADD, the page buffer control signals PBSIG, and the column address CADD. For example, when the command CMD input to the control circuit 180 corresponds to a program operation, the control circuit 180 controls the peripheral circuit 170 such that the program operation of the memory block selected by the address ADD is performed. When the command CMD input to the control circuit 180 corresponds to a read operation, the control circuit 180 controls the peripheral circuit 170 to perform the read operation of the memory block selected by the address ADD and output the read data. When the command CMD input to the control circuit 180 corresponds to an erase operation, the control circuit 180 controls the peripheral circuit 170 to perform the erase operation of the selected memory block.

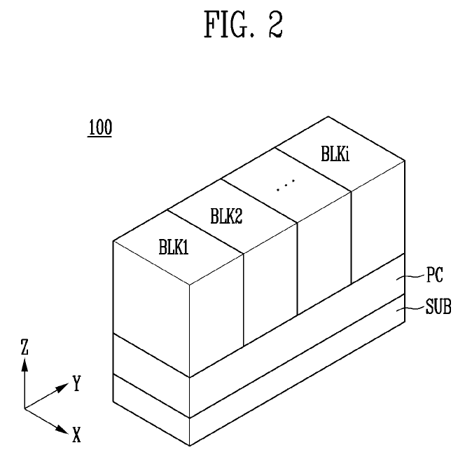

FIG. 2 is an isometric diagram illustrating the memory device 100 according to an embodiment of the present disclosure.

Referring to FIG. 2, the memory device 100 includes a peripheral circuit structure PC and the memory blocks BLK1 to BLKi arranged over a substrate SUB. The memory blocks BLK1 to BLKi overlap or are disposed over the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by a selective epitaxial growth method.

The peripheral circuit structure PC includes the row decoder 130, the column decoder 150, the page buffer group 140, the control circuit 180, and so forth that include a circuit that controls operation of the memory blocks BLK1 to BLKi. For example, the peripheral circuit structure PC may include one or more NMOS transistors, PMOS transistors, resistors, capacitors, and so forth electrically coupled to the memory blocks BLK1 to BLKi. The peripheral circuit structure PC may be arranged between the substrate SUB and the memory blocks BLK1 to BLKi.

Each of the memory blocks BLK1 to BLKi includes a source structure, bit lines, cell strings electrically coupled to the source structure and the bit lines, word lines electrically coupled to the cell strings, and select lines electrically coupled to the cell strings. Each of the cell strings includes memory cells and select transistors coupled in series. Each of the select lines is used as a gate electrode of a corresponding select transistor, and each of the word lines is used as a gate electrode of a corresponding memory cell.

In an embodiment, the substrate SUB, the peripheral circuit structure PC, and the memory blocks BLK1 to BLKi are stacked in a different order than the order shown in FIG. 2. For example, the peripheral circuit structure PC may be located over or on top of the memory blocks BLK1 to BLKi.

In an alternative embodiment, the peripheral circuit structure PC is arranged in an area of the substrate SUB that does not overlap the memory blocks BLK1 to BLKi. For example, the peripheral circuit structure PC and the memory blocks BLK1 to BLKi may be located in different regions of the substrate SUB that do not vertically overlap.

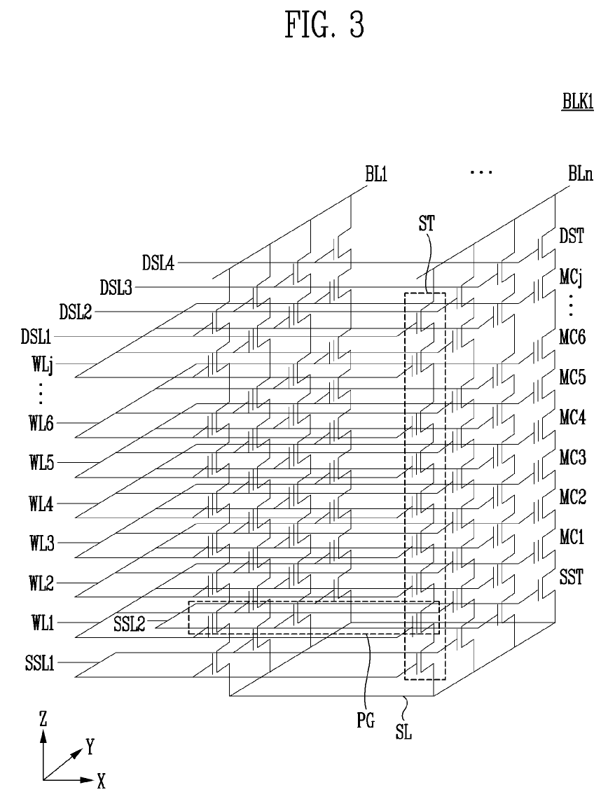

FIG. 3 is a circuit diagram illustrating a connection configuration of a memory block according to an embodiment of the present disclosure.

FIG. 3 is a circuit diagram illustrating components included in the first memory block BLK1. FIG. 3 illustrates components included in the first memory block BLK1. The second memory block BLK2 to the i-th memory block BLKi each include components similar to those shown in FIG. 3.

Referring to FIG. 3, the first memory block BLK1 includes cell strings ST coupled between a first bit line BL1 to an n-th bit line BLn and the source line SL. Because the bit lines BL1 to BLn extend in a Y direction and are spaced apart in an X direction, the cell strings ST are spaced apart in the X direction and the Y direction. For example, the cell strings ST are coupled between the first bit line BL1 and the source line SL, and the cell strings ST are arranged between the second bit line BL2 and the source line SL. Similarly, the cell strings ST are arranged between the n-th bit line BLn and the source line SL. The cell strings ST extend in a Z direction.

For example, one of the cell strings ST coupled to the n-th bit line BLn includes the source select transistor SST, a first memory cell MC1 to a j-th memory cell MCj, and a drain select transistor DST, where j is an integer greater than 1. FIG. 3, which illustrates the first memory block BLK1, is a diagram roughly illustrating a structure of a memory block, and the quantity of source select transistors, such as SST, memory cells, such as MC1 to MCj, and drain select transistors, such as DST, included in the cell strings ST may vary depending on the memory device.

Gates of the source select transistors SST included in different cell strings are coupled to a first source select line SSL1 or a second source select line SSL2. Gates of the memory cells MC1 to MCj are coupled to first to j-th word lines WL1 to WLj, respectively. Each of gates of the drain select transistors DST are coupled to one of the first drain select line DSL1 to the fourth drain select line DSL4.

The source select transistors SST arranged in the X direction are coupled to the same source select line, and the source select transistors SST arranged in the Y direction are coupled to separate source select lines. For example, a first set of the source select transistors SST arranged in the Y direction is coupled to the first source select line SSL1, and a second set of the source select transistors of the source select transistors SST is coupled to the second source select line SSL2. The second source select line SSL2 is a line separated from the first source select line SSL1. Therefore, a voltage applied to the first source select line SSL1 is the same voltage as or a different voltage from a voltage applied to the second source select line SSL2.

Among the memory cells MC1 to MCj, memory cells formed on the same layer are coupled to the same word line. For example, the first memory cell MC1 included in the different cell strings ST is coupled in common to the first word line WL1, and the j-th memory cell MCj included in the different cell string ST is coupled in common to the j-th word line WLj. A group of memory cells included in the different cell strings ST and coupled to the same word line forms a page PG. Program and read operations are performed on a page PG basis.

The drain select transistors DST arranged in the Y direction are coupled to the drain select lines DSL1 to DSL4 that are separated. For example, the drain select transistors DST arranged in the X direction are coupled to the same drain select line, and the drain select transistors DST arranged in the Y direction are coupled to the drain select lines DSL1 to DSL4 that are separated. Because the drain select lines DSL1 to DSL4 are isolated from each other, different voltages may be applied to each of the drain select lines DSL1 to DSL4.

According to the present disclosure, two or more cell strings ST are arranged in each channel opening that extends through a stack. A structure and method of manufacturing a memory device in which two cell strings ST are located in a single channel opening is described.

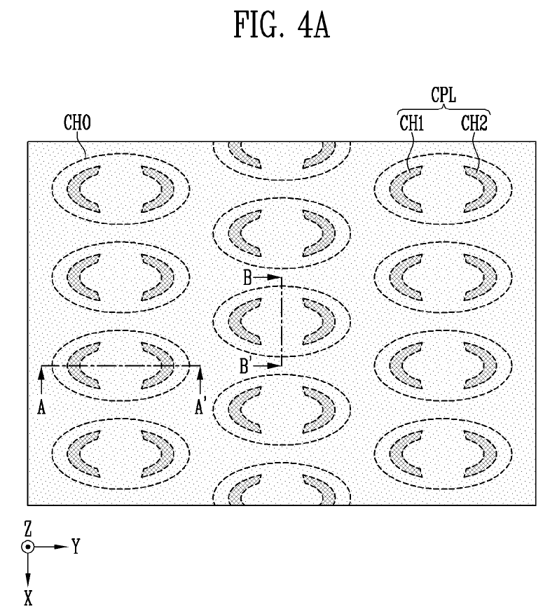

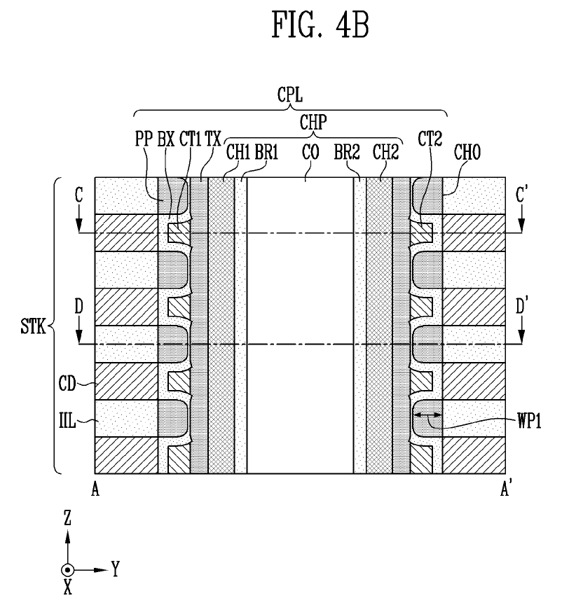

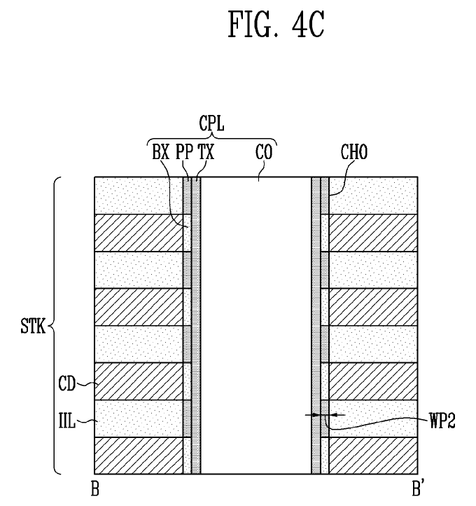

FIGS. 4A-4C include a plan view and cross-sectional views illustrating a structure of the memory device 100 according to an embodiment of the present disclosure.

FIG. 4A is a plan view of the memory device 100 of the present disclosure. For example, FIG. 4A is a plan view of a section of one of the memory blocks BLK1 to BLKi.

Referring to FIG. 4A, channel openings CHO are arranged in the X direction and the Y direction. For example, the channel openings CHO are arranged in alignment in the X direction. The channel openings CHO are offset or staggered with respect to each other in the Y direction.

The channel openings CHO have an elliptical shape in plan view. The channel openings CHO each have the minor axis in the X direction and the major axis in the Y direction in plan view. The channel opening CHO may have an elliptical shape having the major axis extending in the Y direction in a plane.

Cell plugs CPL are formed in a corresponding channel opening CHO. The cell plugs CPL may fill the channel openings CHO. The cell plugs CPL are arranged in the X direction and the Y direction. Each of the cell plugs CPL may have an elliptical or oval cross-section. Each of the cell plugs CPL may have an elliptical shape with the major axis in the Y direction and the minor axis in the X direction in plan view. Each of the cell plugs CPL may have an elliptical column shape.

Each of the cell plugs CPL includes a first channel pattern CH1 and a second channel pattern CH2. The first channel pattern CH1 is separated from the second channel pattern CH2. The first channel pattern CH1 is spaced apart from the second channel pattern CH2 in the Y direction.

The first channel pattern CH1 forms a first cell string of the cell strings ST, and the second channel pattern CH2 forms a second cell string of the cell strings ST. One of the cell plugs CPL corresponds to two cell strings ST. Because two cell strings ST are included in one cell plug CPL, the integration density of the memory device 100 may be improved compared to when one cell string ST is formed in each cell plug CPL.

FIG. 4B is a cross-sectional view taken along line A-A’ of FIG. 4A. FIG. 4C is a cross-sectional view taken along line B-B’ of FIG. 4A. FIGS. 4B and 4C are not necessarily drawn to scale with respect to FIG. 4A. FIG. 4B is a cross-sectional view of the cell plug CPL through the major axis, and FIG. 4C is a cross-sectional view of the cell plug CPL through the minor axis.

Referring to FIGS. 4B and 4C, a stack STK includes conductive layers CD and interlayer insulating layers IIL. The conductive layers CD are alternately stacked with the interlayer insulating layers IIL in the Z direction. The conductive layers CD may include at least one of tungsten (W), cobalt (Co), nickel (Ni), molybdenum (Mo), silicon (Si), or polysilicon (poly-Si). The conductive layers CD correspond to gate lines. For example, the conductive layers CD correspond to the drain select lines DSL, the word lines WL, and the source select lines SSL in FIG. 3. The interlayer insulating layers IIL may include an oxide layer. For example, the interlayer insulating layers IIL may include a silicon oxide layer.

The channel opening CHO extends through the stack STK. The channel opening CHO extends through the conductive layers CD and the interlayer insulating layers IIL. Each of the channel openings CHO extends in the Z direction. The cell plug CPL is formed in the channel opening CHO.

The channel opening CHO has an elliptical shape in plan view in an embodiment. Each of the channel openings CHO has the minor axis in the X direction and the major axis in the Y direction in plan view. The length of the channel opening CHO in the Y direction is greater than the length of the channel opening CHO in the X direction. The length of the cell plug CPL in the Y direction is greater than the length of the cell plug CPL in the X direction.

The cell plug CPL includes protruding patterns PP, a blocking layer BX, first data storage patterns CT1, second data storage patterns CT2, a tunneling layer TX, the channel patterns CH1 and CH2, a first barrier pattern BR1 and a second barrier pattern BR2, and a core pillar CO. The channel patterns CH1 and CH2, the barrier patterns BR1 and BR2, and the core pillar CO is referred to as a channel pillar CHP, although the channel pillar CHP may include fewer or additional components.

The protruding pattern PP is located between the channel pillar CHP and each of the interlayer insulating layers IIL. The protruding pattern PP contacts a side surface of each of the interlayer insulating layers IIL in an embodiment. The protruding patterns PP extend between the center of the channel opening CHO and a side surface of the stack STK. The protruding patterns PP are spaced apart in the Z direction. The height of each of the protruding patterns PP is equal to, less than, or greater than the height of each of the interlayer insulating layers IIL. The height of each of the protruding patterns PP is indicated in the Z direction.

The thickness of each of the protruding patterns PP varies depending on location. For example, each of the protruding patterns PP has a first thickness WP1 along the major axis of the ellipse and a second thickness WP2 thinner than the first thickness WP1 along the minor axis of the ellipse. In an embodiment of the present disclosure, the major axis of the ellipse is in the Y direction, and the minor axis of the ellipse is in the X direction.

The blocking layer BX extends over surfaces of the protruding patterns PP and the side surface of the stack STK. The blocking layer BX contacts the surfaces of the protruding patterns PP. The blocking layer BX contacts side surfaces of the conductive layers CD. The thickness of the blocking layer BX may vary depending on a location where the blocking layer BX is formed. For example, the blocking layer BX may have a smallest or minimal thickness on an innermost surface of each of the protruding patterns PP. The blocking layer BX may include an oxide layer, such as a silicon oxide layer, an oxynitride layer, such as a silicon oxynitride layer, or a combination thereof.

The first data storage patterns CT1 and the second data storage patterns CT2 are arranged between the protruding patterns PP in the Z direction. The first data storage patterns CT1 are spaced apart in the Z direction. The second data storage patterns CT2 are spaced apart in the Z direction. The first data storage patterns CT1 are spaced apart from the second data storage patterns CT2 in the Y direction. Referring to FIG. 4C, the data storage patterns CT1 and CT2 are not observed in a cross section obtained by cutting the cell plug CPL in the X direction along the minor axis of the ellipse.

The data storage patterns CT1 and CT2 are formed in a space or a pocket formed between consecutive protruding patterns PP in the Z direction. The data storage patterns CT1 and CT2 overlap the protruding patterns PP in the Z direction in an embodiment. In one or more locations on the X-Y plane, the protruding patterns PP are alternately arranged with the data storage patterns CT1 or CT2 in the Z direction. The data storage patterns CT1 and CT2 contact the blocking layer BX. The blocking layer BX extends between the protruding patterns PP and the data storage patterns CT1 or CT2. The data storage patterns CT1 and CT2 may include a nitride layer or a variable resistance material.

The first data storage patterns CT1 form a first cell string of the cell strings ST with the first channel pattern CH1, and the second data storage patterns CT2 form a second cell string of the cell strings ST with the second channel pattern CH2. Thus, one cell plug CPL corresponds to two cell strings ST.

The tunneling layer TX extends in the Z direction. The tunneling layer TX covers the protruding patterns PP, the blocking layer BX, and the first and second data storage patterns CT1 and CT2. The tunneling layer TX contacts a section of an inner surface of the blocking layer BX. The tunneling layer TX contacts inner surfaces of the data storage patterns CT1 and CT2. The tunneling layer TX contacts one or more of the inner surfaces of the protruding patterns PP. The tunneling layer TX may include an oxide layer, such as a silicon oxide layer, an oxynitride layer, such as a silicon oxynitride layer, or a combination thereof.

The channel pillar CHP includes the channel patterns CH1 and CH2, the barrier patterns BR1 and BR2, and the core pillar CO. The first channel pattern CH1 is spaced apart from the second channel pattern CH2 in the Y direction. The first barrier pattern BR1 is spaced apart from the second barrier pattern BR2 in the Y direction. The core pillar CO separates the first channel pattern CH1 from the second channel pattern CH2. The channel pillar CHP extends in the Z direction. Although not shown in FIG. 4B, each of the cell plugs CPL includes a capping pattern or layer coupled to the channel patterns CH1 and CH2 on the core pillar CO. The channel patterns CH1 and CH2 and the capping patterns or layers may include an undoped silicon layer or doped silicon layer. The barrier patterns BR1 and BR2 and the core pillar CO may include an insulating layer, such as an oxide layer.

Referring to FIGS. 4A and 4B, each of the cell plugs CPL has a shape that is symmetrical in the X direction and in the Y direction, for example, with respect to one or more symmetry planes. For example, the first data storage pattern CT1 is symmetrical with the second data storage pattern CT2 in the Y direction with respect to a first symmetry plane. The first channel pattern CH1 is formed symmetrically with respect to the second channel pattern CH2 with respect to the first symmetry plane. The first data storage pattern CT1 and the first channel pattern CH1 are similar to the second data storage pattern CT2 and the second channel pattern CH2, respectively.

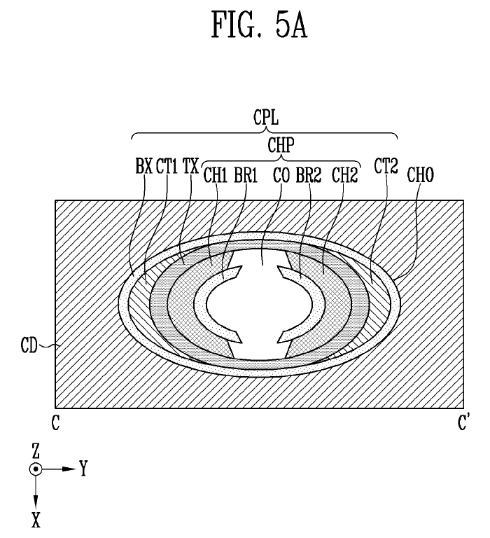

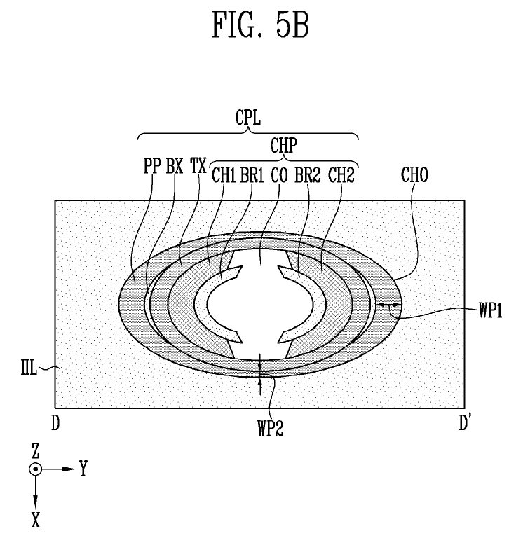

FIGS. 5A and 5B are plan views illustrating a structure of the memory device 100 according to an embodiment of the present disclosure.

FIG. 5A is a cross-sectional view taken along line C-C’ of FIG. 4B. FIG. 5B is a cross-sectional view taken along line D-D’ of FIG. 4B. FIG. 5A shows a cross section of the cell plug CPL at levels corresponding to the conductive layers CD, and FIG. 5B shows a cross section of the cell plug CPL at levels corresponding to the interlayer insulating layers IIL.

Referring to FIGS. 5A and 5B, the cell plug CPL is formed in the channel opening CHO. Each of the channel openings CHO have an elliptical shape in plan view. Each of the channel openings CHO has the minor axis in the X direction and the major axis in the Y direction in plan view in an embodiment. The cell plugs CPL have an elliptical shape with the major axis in the Y direction. The cell plug CPL may have an elliptical column shape.

The cell plug CPL includes the channel pillar CHP. The channel pillar CHP includes the first channel pattern CH1 spaced apart from the second channel pattern CH2 spaced apart in the Y direction. The channel patterns CH1 and CH2 each extend in the Z direction. The channel pillar CHP include the core pillar CO located between the channel patterns CH1 and CH2. The core pillar CO insulates the first channel pattern CH1 from the second channel pattern CH2. The core pillar CO extends in the Z direction. The channel pillar CHP includes the first barrier pattern BR1 located between the first channel pattern CH1 and the core pillar CO, and the second barrier pattern BR2 is located between the second channel pattern CH2 and the core pillar CO. The first barrier pattern BR1 is spaced apart from the second barrier pattern BR2 in the Y direction. The barrier patterns BR1 and BR2 each extend in the Z direction.

The channel pillar CHP has an elliptical column shape. The channel pillar CHP has an elliptical shape in a plane with the major axis in the Y direction. The length of the channel pillar CHP in the Y direction is longer than the length of the channel pillar CHP in the X direction. The major axis of the channel pillar CHP in plan view and the major axis of the cell plug CPL in plan view are co-planar or parallel. For example, each of the channel pillar CHP and the cell plug CPL have an elliptical shape with the major axis in the Y direction in plan view.

The cell plug CPL includes the tunneling layer TX surrounding the channel pillar CHP. The tunneling layer TX extends over outer surfaces of the channel patterns CH1 and CH2. The tunneling layer TX contacts the outer surfaces of the channel patterns CH1 and CH2. The tunneling layer TX contacts at least a section of a surface of the core pillar CO. The tunneling layer TX has an elliptical shape with the major axis in the Y direction and the minor axis in the X direction in plan view. The tunneling layer TX is cylindrical with an elliptical shape in the X-Y plane. The tunneling layer TX may extend in the Z direction.

The cell plug CPL includes the first data storage pattern CT1 located between the first channel pattern CH1 and each of the conductive layers CD. The cell plug CPL includes the second data storage pattern CT2 located between the second channel pattern CH2 and each of the conductive layers CD.

The first data storage patterns CT1 are spaced apart from the second data storage patterns CT2 in the Y direction. The first data storage pattern CT1 and the second data storage pattern CT2 located at the same level are arranged along the major axis of the ellipse. For example, in FIG. 5A, the second data storage pattern CT2 is located a distance from the first data storage pattern CT1 in the Y direction.

The first data storage patterns CT1 are insulated from the second data storage patterns CT2. The first data storage pattern CT1 is insulated from the second data storage pattern CT2 located at the same level by the tunneling layer TX. The first data storage patterns CT1 are located between the tunneling layer TX and the blocking layer BX. The second data storage patterns CT2 are located between the tunneling layer TX and the blocking layer BX. Because the first data storage pattern CT1 is separated from the second data storage pattern CT2 in the Y direction, one cell plug CPL corresponds to or includes two cell strings ST.

The first data storage patterns CT1 are spaced apart in the Z direction. For example, the first data storage patterns CT1 are located at levels corresponding to the conductive layers CD and are not located at levels corresponding to the interlayer insulating layers IIL. The first data storage patterns CT1 overlap the conductive layers CD in the X direction and the Y direction. The first data storage patterns CT1 do not overlap the interlayer insulating layers IIL in the X direction and the Y direction.

The second data storage patterns CT2 are spaced apart in the Z direction. For example, the second data storage patterns CT2 are located at levels corresponding to the conductive layers CD and are not located at levels corresponding to the interlayer insulating layers IIL. The second data storage patterns CT2 overlap the conductive layers CD in the X direction and the Y direction. The second data storage patterns CT2 do not overlap the interlayer insulating layers IIL in the X direction and the Y direction.

The cell plug CPL includes the protruding patterns PP that contact side surfaces of the interlayer insulating layers IIL. The protruding patterns PP are spaced apart in the Z direction. For example, the protruding patterns PP are located at levels corresponding to the interlayer insulating layers IIL and are not located at levels corresponding to the conductive layers CD. The protruding patterns PP overlap the interlayer insulating layers IIL in the X direction and the Y direction. The protruding patterns PP do not overlap the conductive layers CD in the X direction and the Y direction.

The protruding patterns PP surround the channel pillar CHP. The protruding patterns PP surround the channel patterns CH1 and CH2. Each of the protruding patterns PP have a ring or oval shape surrounding the channel patterns CH1 and CH2.

The data storage patterns CT1 and CT2 are located between the protruding patterns PP. For example, at least one first data storage pattern CT1 and at least one second data storage pattern CT2 are located between consecutive protruding patterns PP in the Z direction. The first data storage patterns CT1 are spaced apart in the Z direction between the protruding patterns PP. Similarly, the second data storage patterns CT2 are spaced apart in the Z direction between the protruding patterns PP. The first data storage patterns CT1 consecutively arranged in the Z direction are spaced apart between the blocking layer BX and the protruding patterns PP. The second data storage patterns CT2 consecutively arranged in the Z direction are spaced apart between the blocking layer BX and the protruding patterns PP. The protruding patterns PP overlap the data storage patterns CT1 and CT2 in the Z direction.

The protruding patterns PP have different thicknesses depending on location. Each of the protruding patterns PP has the first thickness WP1 along the major axis in the Y direction and the second thickness WP2 along the minor axis in the X direction. For example, the first thickness WP1 is the largest or maximum thickness of each of the protruding patterns PP, and the second thickness WP2 is the smallest or minimal thickness of each of the protruding patterns PP.

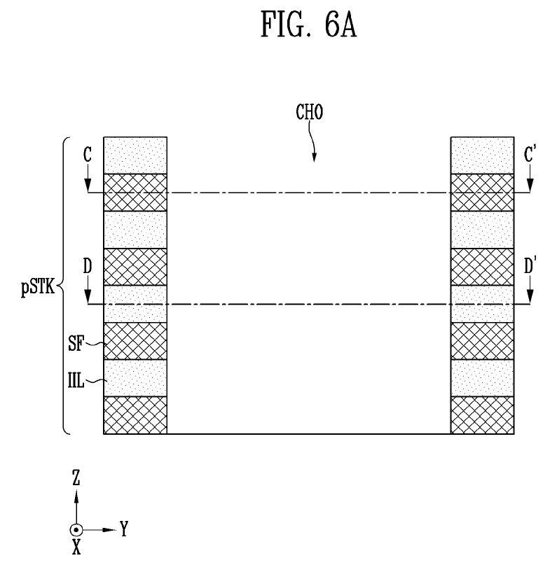

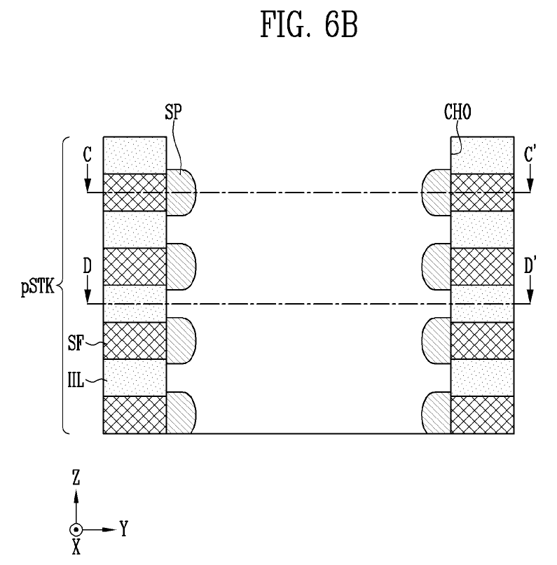

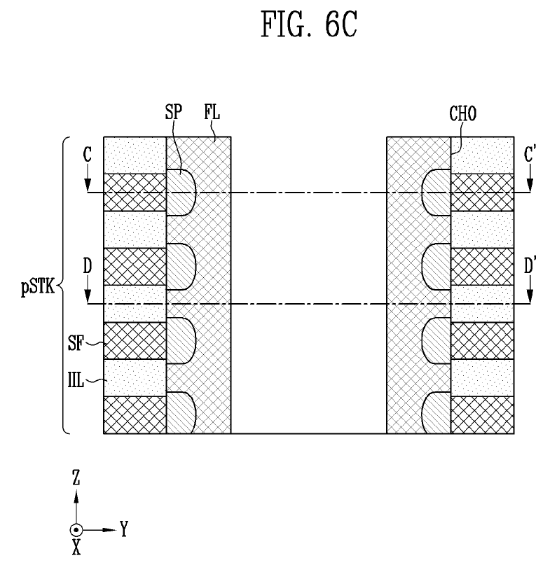

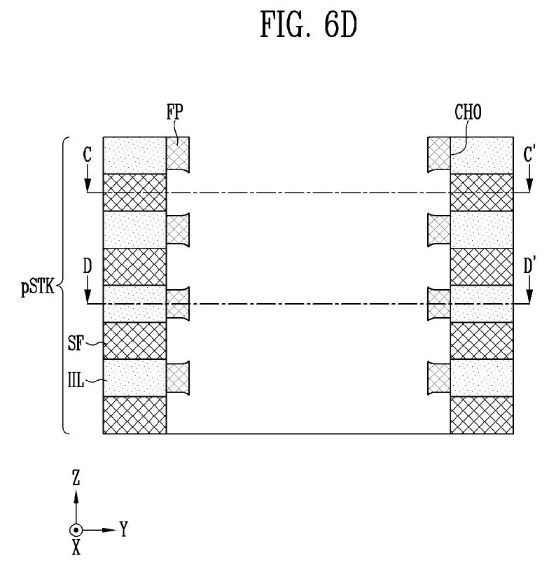

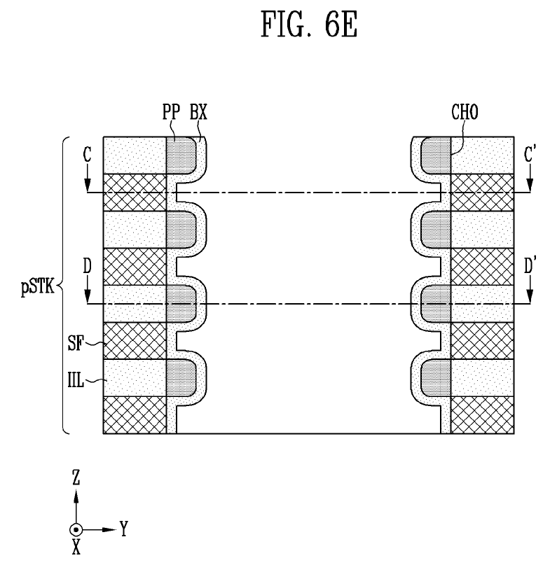

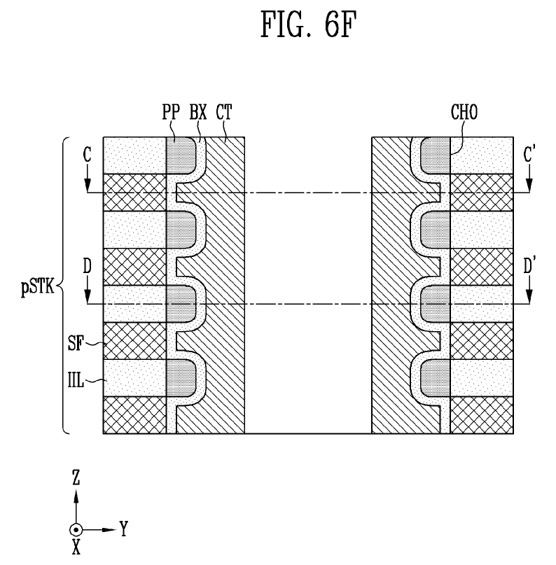

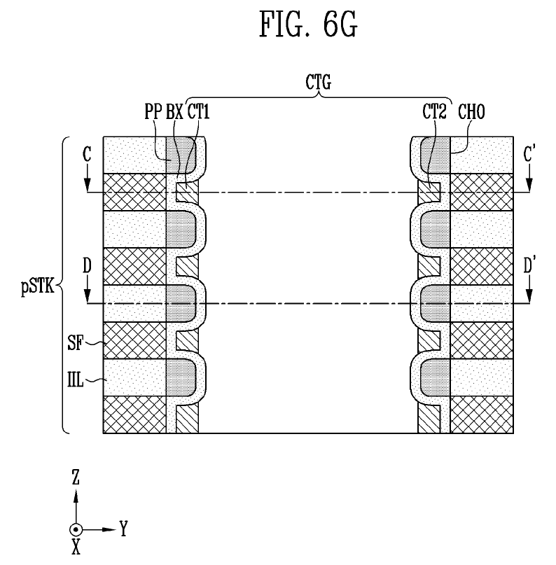

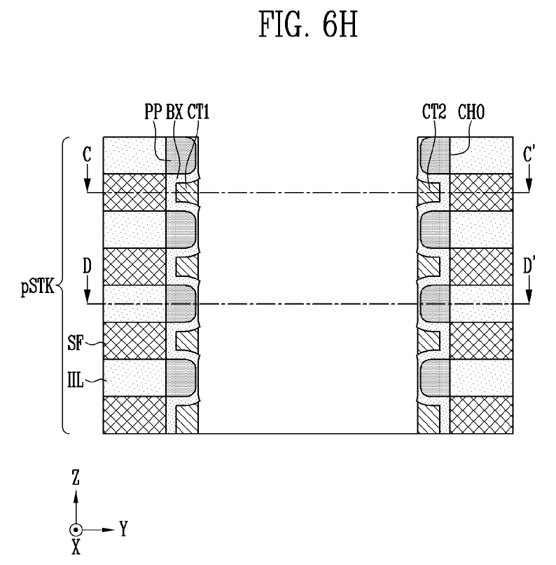

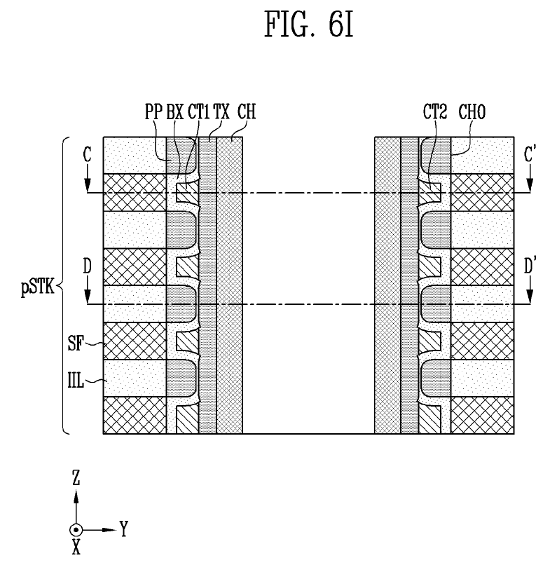

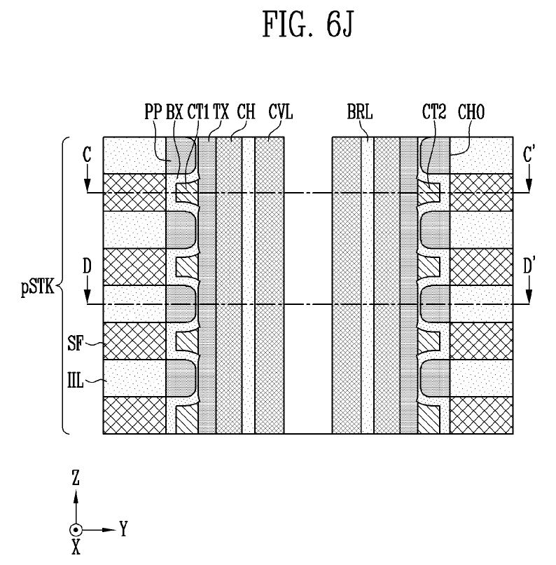

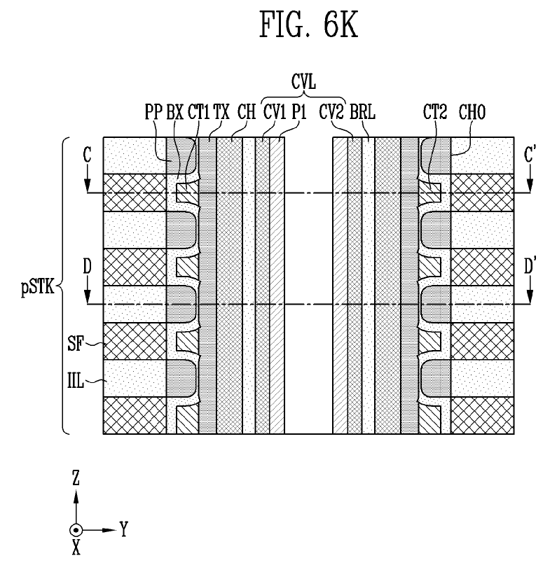

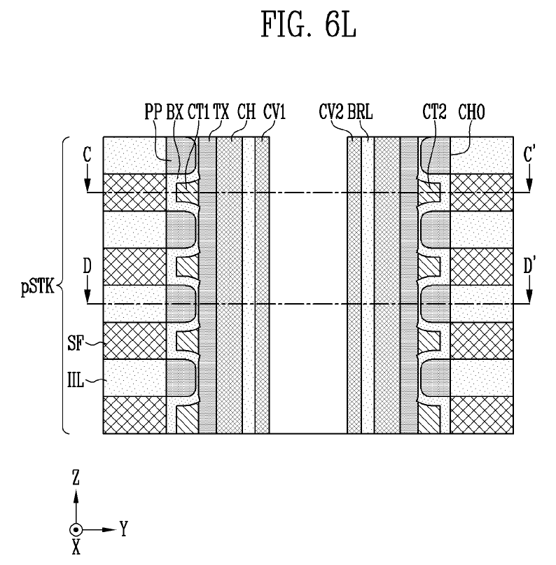

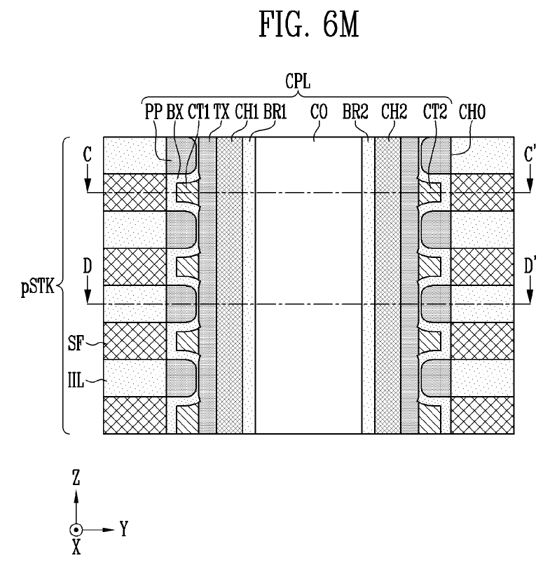

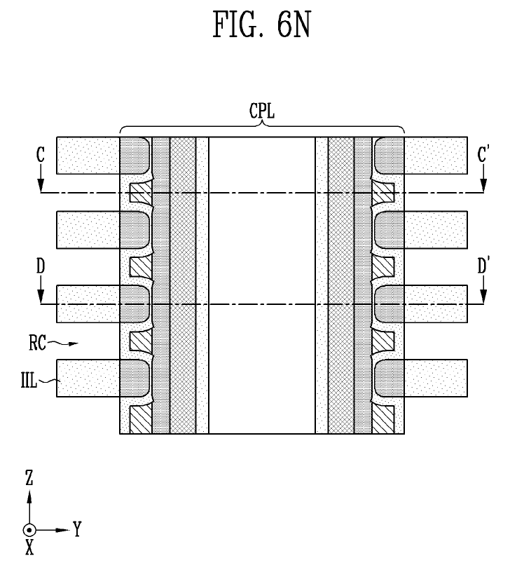

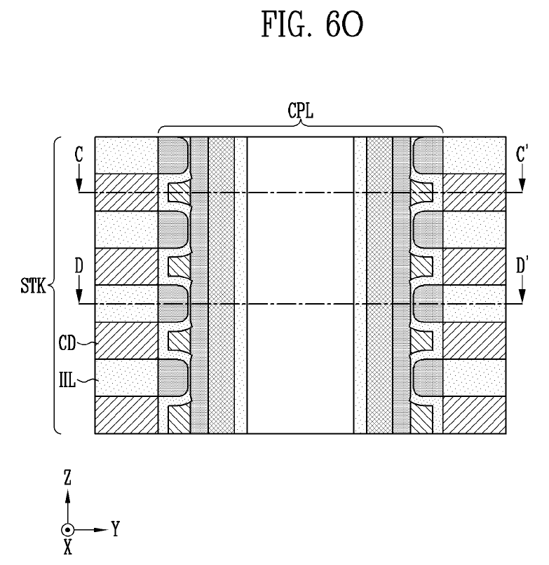

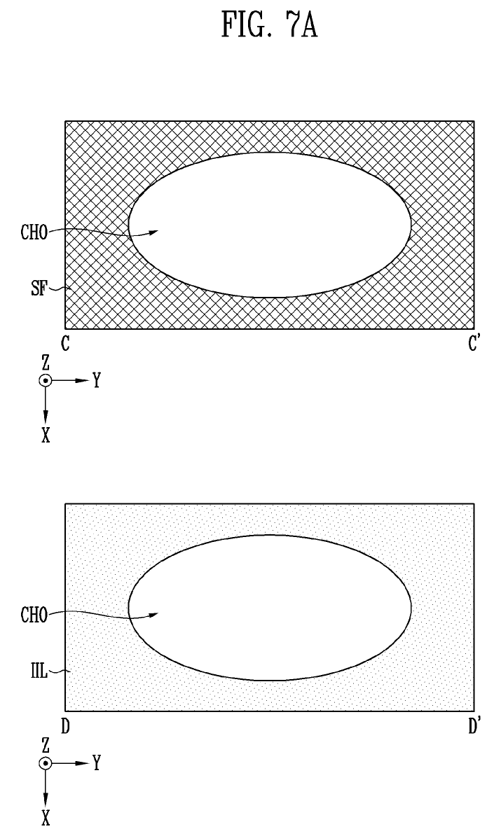

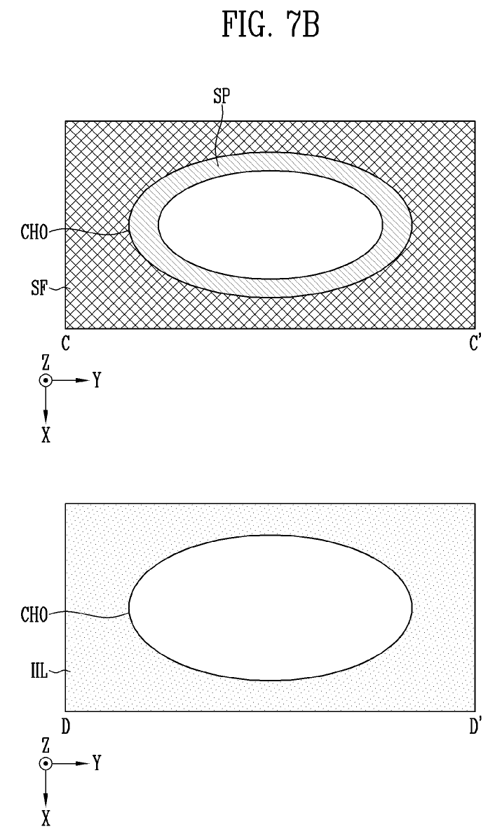

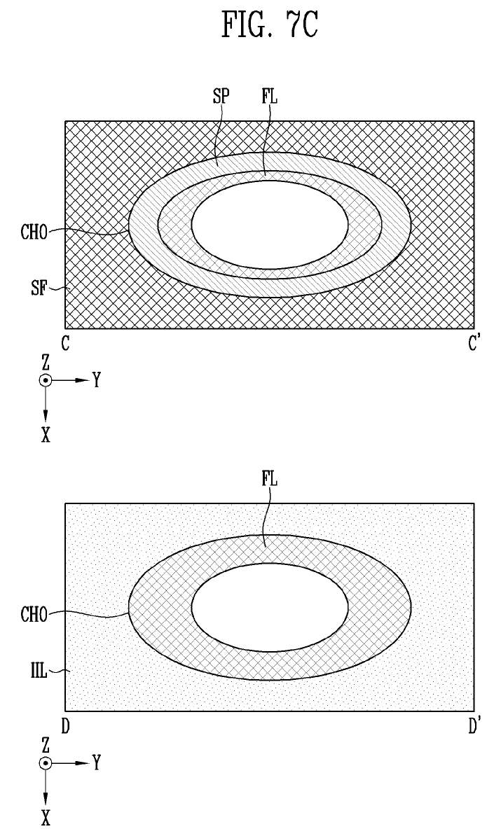

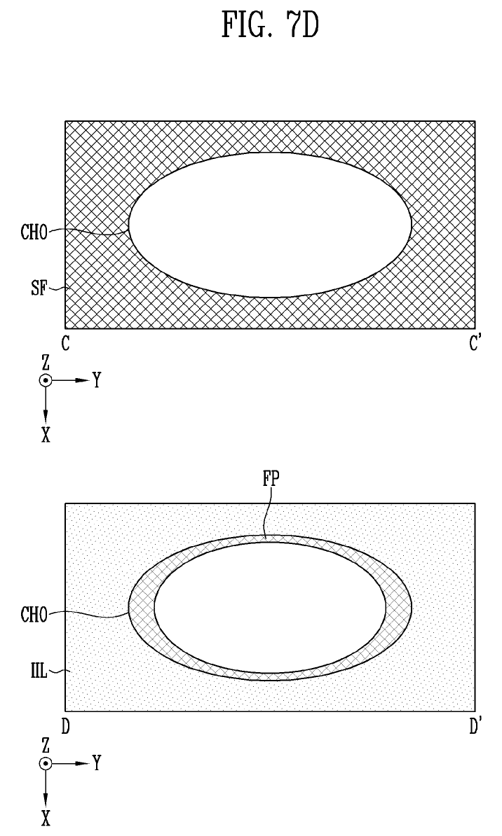

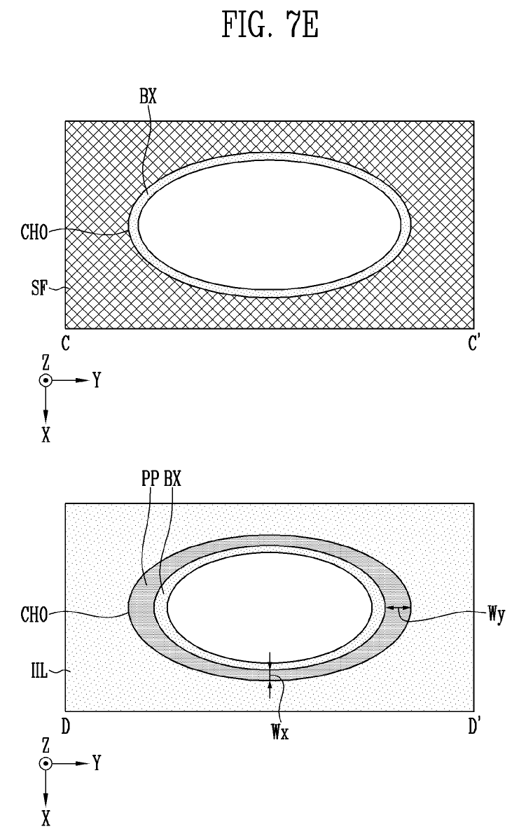

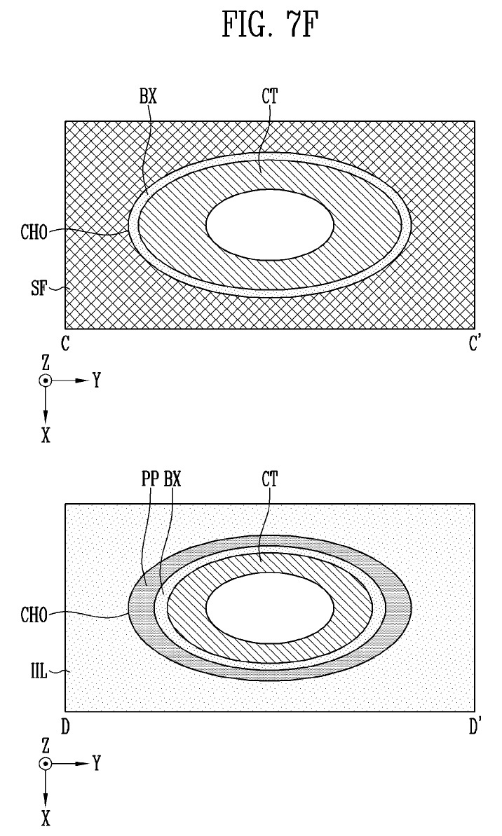

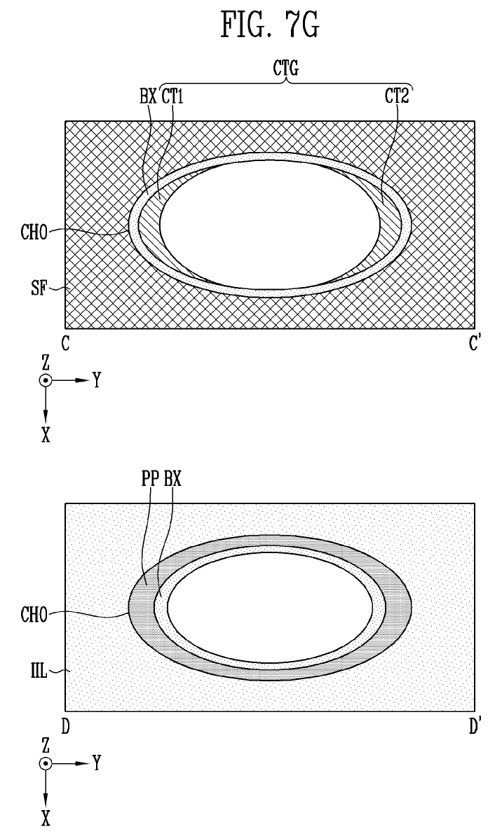

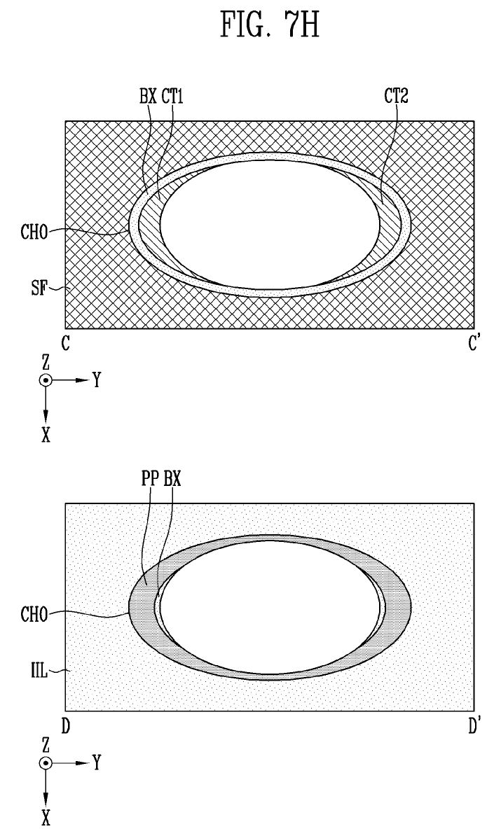

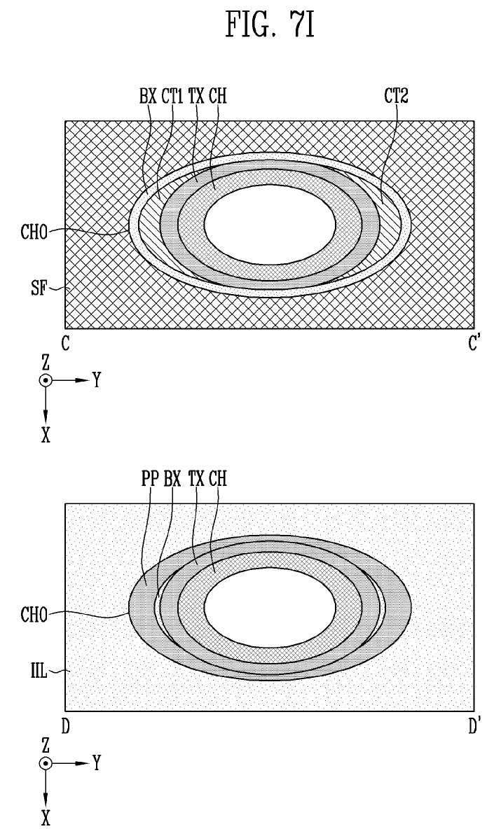

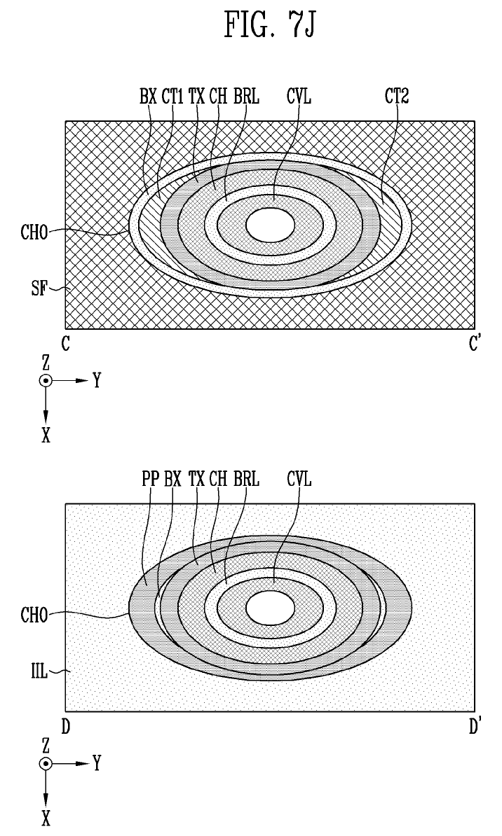

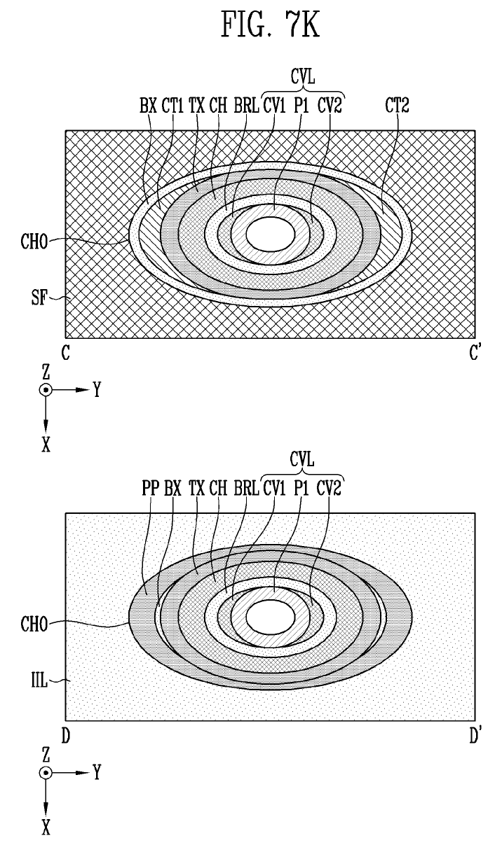

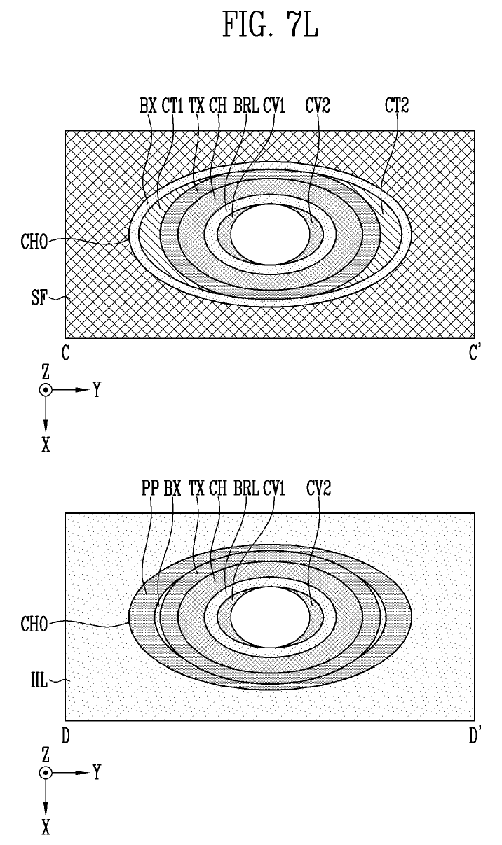

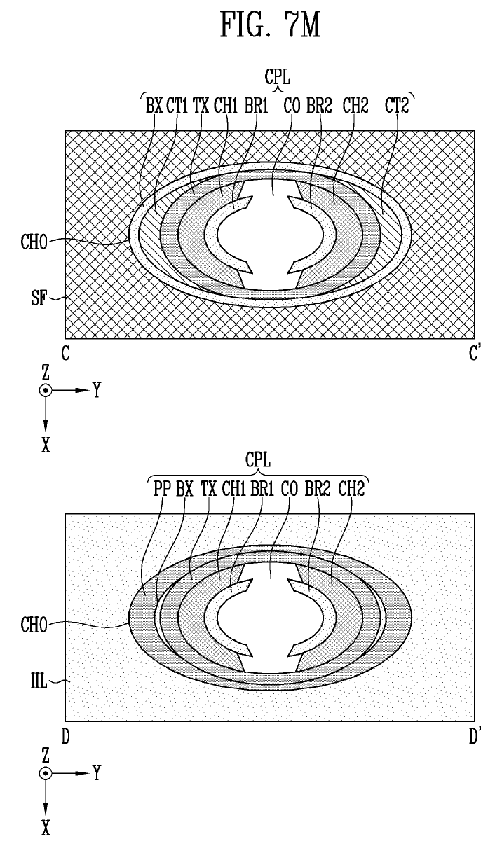

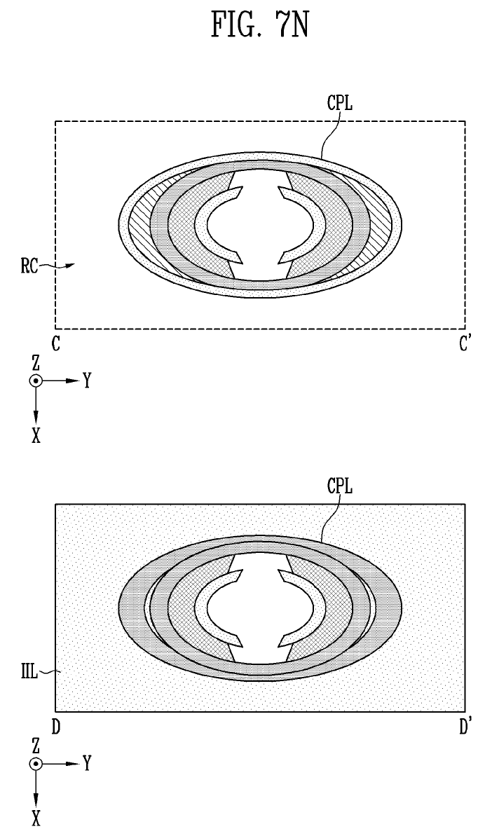

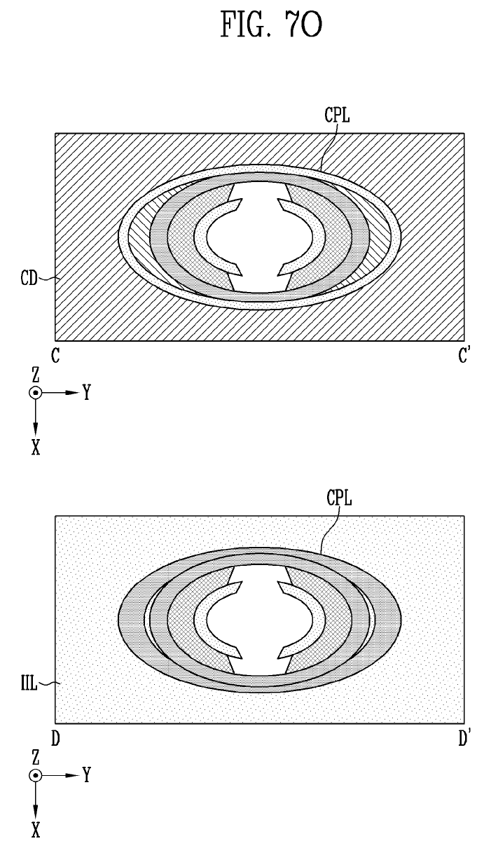

When the thickness of the protruding patterns PP along the major axis in the Y direction is greater than the thickness of the protruding patterns PP along the minor axis in the X direction, the second data storage patterns CT2 may be spaced apart from the first data storage patterns CT1 in the Y direction. Because the data storage patterns CT1 and CT2 are formed within the spaces between the protruding patterns PP that are separated in the Z direction and positioned at both sides in the Y direction, the data storage patterns CT1 and CT2 are formed only in the Y direction regions where the protruding patterns PP have a greater thickness in the Y direction. A process of forming the first data storage pattern CT1 spaced apart from the second data storage pattern CT2 in the Y direction is described with reference to FIGS. 6F, 6G, 7F, and 7G.

The cell plug CPL includes the blocking layer BX. The blocking layer BX contacts the side surfaces of the conductive layers CD. Referring to FIG. 5A, the blocking layer BX contacts outer surfaces of the first data storage patterns CT1, outer surfaces of the second data storage patterns CT2, and a section of an outer surface of the tunneling layer TX. At levels corresponding to the conductive layers CD, the blocking layer BX is an outer surface of the cell plug CPL. Referring to FIG. 5B, the blocking layer BX extends between the protruding patterns PP and the tunneling layer TX. At levels corresponding to the interlayer insulating layers IIL, the blocking layer BX is located on the inner surfaces of the protruding patterns PP. At levels corresponding to the interlayer insulating layers IIL, the blocking layer BX is located in the Y direction or along the major axis of the ellipse and is not located along the minor axis of the ellipse. Referring to FIG. 4B, the blocking layer BX extends between the protruding patterns PP and the first data storage patterns CT1. The blocking layer BX extends between the protruding patterns PP and the second data storage patterns CT2.

According to the present disclosure, the cell plug CPL includes data storage patterns separated from each other in vertical and horizontal directions. The first data storage patterns CT1 are spaced apart in the Z direction, and the second data storage patterns CT2 are spaced apart in the Z direction. The second data storage patterns CT2 are spaced apart from the first data storage patterns CT1 in the Y direction.

Because the data storage patterns CT1, CT2 formed at different layers or levels are separated from each other, negative charges trapped in the data storage patterns by a program operation do not move to other data storage patterns located nearby in the vertical direction. Because the data storage patterns formed at different layers are separated from each other, the influence of word lines at different layers adjacent in the vertical or Z direction may be reduced. Therefore, the reliability of the memory device 100 may be improved because the data storage patterns are separated in the Z direction.

Because the first data storage pattern CT1 and the second data storage pattern CT2 located within a given layer are separated in the horizontal or Y direction, and the first channel pattern CH1 is separated from the second channel pattern CH2, one cell plug CPL corresponds to two cell strings ST. Therefore, the integration density of the memory device 100 may be improved.

FIGS. 6A-6O are cross-sectional diagrams of a memory device manufactured utilizing a method of manufacturing the memory device 100 according to an embodiment of the present disclosure. FIGS. 7A-7O are plan views of a memory device manufactured utilizing a method of manufacturing the memory device 100 according to an embodiment of the present disclosure. FIGS. 7A-7O correspond to FIGS. 6A-6O, respectively, and each of FIGS. 7A-7O is a cross-sectional view taken along line C-C’ and a cross-sectional view taken along line D-D’ of a corresponding one FIGS. 6A-6O.

Referring to FIGS. 6A and 7A, sacrificial layers SF are alternately stacked with the interlayer insulating layers IIL to form a preliminary stack pSTK. The sacrificial layers SF are alternately stacked with the interlayer insulating layers IIL in the Z direction. The interlayer insulating layers IIL may include an insulating material. For example, the interlayer insulating layers IIL may include an oxide layer. The interlayer insulating layers IIL may include a silicon oxide layer or an equivalent oxide material. The sacrificial layers SF may include a material that may be selectively removed in a subsequent process. The sacrificial layers SF may include a material having different etch selectivity from the interlayer insulating layers IIL. The sacrificial layers SF may include a nitride material. For example, the sacrificial layers SF may include a silicon nitride layer.

The channel opening CHO is formed, extending through the preliminary stack pSTK. The channel opening CHO extends through the preliminary stack pSTK in the Z direction. The channel opening CHO extends through the sacrificial layers SF and the interlayer insulating layers IIL in the Z direction. Side surfaces of the sacrificial layers SF and side surfaces of the interlayer insulating layers IIL are exposed through the channel opening CHO. The channel opening CHO may have an elliptical or oval shape with the major axis in the Y direction and the minor axis in the X direction in plan view in an embodiment.

Referring to FIGS. 6B and 7B, sacrificial patterns SP are formed on the sacrificial layers SF exposed through the channel opening CHO. The sacrificial patterns SP are deposited on the side surfaces of the sacrificial layers SF. For example, the sacrificial patterns SP may be layers grown from surfaces of the sacrificial layers SF. The sacrificial patterns SP may be selectively deposited on the surfaces of the sacrificial layers SF by an area selective deposition (ASD) method. The ASD method is a method that selectively deposits a thin film on a particular area.

The sacrificial patterns SP may include a material that is selectively deposited on the material included in the sacrificial layers SF. For example, the sacrificial patterns SP may include a material that is selectively deposited on a nitride material. For example, the sacrificial pattern SP may include SiOC.

The sacrificial patterns SP each have a thickness greater than the thickness of each of the sacrificial layers SF in the Z direction. The thicknesses of the sacrificial patterns SP may be selected such that the consecutive sacrificial patterns SP in the Z direction do not contact each other. Therefore, the side surfaces of the interlayer insulating layers IIL are exposed between the consecutive sacrificial patterns SP in the Z direction.

Referring to FIGS. 6C and 7C, a filling layer FL is formed covering the sacrificial patterns SP. The filling layer FL contacts surfaces of the sacrificial patterns SP. The filling layer FL contacts the side surfaces of the interlayer insulating layers IIL between the sacrificial patterns SP. The filling layer FL may fill any space between the sacrificial patterns SP. The filling layer FL may include polysilicon.

The thickness of the filling layer FL is thinner at levels corresponding to the sacrificial layers SF than the thickness of the filling layer FL at the levels corresponding to the interlayer insulating layers IIL. The thickness of the filling layer FL along the major axis of the channel opening CHO is greater than the thickness of the filling layer FL along the minor axis. When the channel opening CHO has an elliptical shape, the filling layer FL may collect or clump together at opposite ends along the major axis of the ellipse and may have a relatively greater thickness along the major axis.

Referring to FIGS. 6D and 7D, filling patterns FP are formed by removing sections of the filling layer FL. For example, sections of the filling layer FL formed on side surfaces of the sacrificial patterns SP are etched. The filling patterns FP are surrounded by the interlayer insulating layers IIL. The filling patterns FP are not located at the levels corresponding to the sacrificial layers SF. The filling patterns FP are formed between the sacrificial patterns SP. The filling patterns FP are spaced apart in the Z direction. The filling patterns FP contact upper and lower surfaces of the sacrificial patterns SP. The filling patterns FP contact the side surfaces of the interlayer insulating layers IIL. The filling patterns FP may have different thicknesses depending on location. The thickness of each of the filling patterns FP along the major axis in the Y direction is greater than the thickness of each of the filling patterns FP along the minor axis in the X direction.

The sacrificial patterns SP are removed. For example, the sacrificial patterns SP may be removed using an ashing process. As the sacrificial patterns SP are removed, the side surfaces of the sacrificial layers SF are exposed between the filling patterns FP. Alternatively, for example, the sacrificial patterns SP may be removed by a dry or wet etching process. The sacrificial patterns SP may be selectively etched using an etchant or source gas with higher etch selectivity for the sacrificial patterns SP than for the filling patterns FP.

Referring to FIGS. 6E and 7E, the protruding patterns PP are formed by oxidizing the filling patterns FP in an embodiment. The protruding patterns PP are formed on the side surfaces of the interlayer insulating layers IIL. As a result of the oxidation, the protruding patterns PP expand relative to the filling patterns FP. For example, the protruding patterns PP cover the side surfaces of the interlayer insulating layers IIL. The filling patterns FP may include silicon or a material containing silicon, and the protruding patterns PP may be silicon oxide layers.

The protruding patterns PP have different thicknesses depending on a location. A thickness Wy of each of the protruding patterns PP along the major axis in the Y direction is greater than a thickness Wx of each of the protruding patterns PP along the minor axis in the X direction.

The blocking layer BX is formed extending over the surface of the protruding patterns PP. The blocking layer BX is conformally formed on the surfaces of the protruding patterns PP and the side surfaces of the sacrificial layers SF. The blocking layer BX may include an oxide material. The blocking layer BX may have a corrugated shape due to the protruding patterns PP. Recesses are formed on the inner surface of the blocking layer BX. The recesses are located between the protruding patterns PP.

Referring to FIGS. 6F and 7F, a data storage layer CT is formed covering the protruding patterns PP and the blocking layer BX. The data storage layer CT contacts the blocking layer BX. The data storage layer CT fills the recesses between the protruding patterns PP. The data storage layer CT fills the recesses along the blocking layer BX. The data storage layer CT may include a nitride material.

The thickness of the data storage layer CT along the major axis in the Y direction may be greater than the thickness of the data storage layer CT along the minor axis in the X direction. When the channel opening CHO has an elliptical planar shape, the data storage layer CT may collect or clump together at at opposite ends (leftmost and rightmost) of the ellipse along the major axis in the Y direction and thus may have a relatively greater thickness along the major axis in the Y direction than along the minor axis in the X direction.

Referring to FIGS. 6G and 7G, data storage pattern groups CTG is formed by removing a section of the data storage layer CT. For example, the section of the data storage layer CT located at the levels corresponding to the interlayer insulating layers IIL is removed. A dry etching process may be performed to remove the section of the data storage layer CT. For example, an anisotropic dry etching process may be performed such that the data storage layer CT remains in the recesses of the blocking layer BX. During the anisotropic dry etching process, a source gas with higher etch selectivity for the data storage layer CT than for the blocking layer BX may be used. The data storage layer CT remaining in the recesses of the blocking layer BX at one level in the Z direction forms a data storage pattern group CTG. One first data storage pattern CT1 and one second data storage pattern CT2 located at the same level are referred to as a data storage pattern groups CTG.

The data storage pattern groups CTG are spaced apart in the Z direction in the channel opening CHO. For example, the first data storage patterns CT1 are spaced apart in the Z direction. The second data storage patterns CT2 are spaced apart in the Z direction. The data storage pattern groups CTG are located between the protruding patterns PP. The data storage pattern groups CTG are alternately arranged with the protruding patterns PP in the Z direction. The data storage pattern groups CTG are located in the recesses of the blocking layer BX.

The first data storage pattern CT1 and the second data storage pattern CT2 included in one data storage pattern group CTG are spaced apart in the Y direction. As shown in FIG. 7F, because the data storage layer CT is thicker in along the major axis in the Y direction than along the minor axis in the X direction, a section of the data storage layer CT located in the X direction is removed first when the section of the data storage layer CT is etched. Therefore, the first data storage patterns CT1 are separated from the second data storage patterns CT2 in the Y direction.

Referring to FIGS. 6H and 7H, a section of the blocking layer BX is etched. The section of the blocking layer BX that extends or protrudes farther inward than the data storage patterns CT1 and CT2 may be etched. After the section of the blocking layer BX is etched, the inner surfaces within the cell plug CPL may have a relatively uniform vertical surface.

At levels corresponding to the interlayer insulating layers IIL, a section of the blocking layer BX located along the minor axis in the X direction is removed, while a section located along the major axis in the Y direction remains. As the section of the blocking layer BX is removed, the protruding patterns PP are exposed. At the levels corresponding to the interlayer insulating layers IIL, regions of the protruding patterns PP located along the major axis in the X direction are etched. The thickness of each of the protruding patterns PP along the major axis in the Y direction are thicker than the thickness of each of the protruding patterns PP along the minor axis in the X direction.

In an embodiment, the blocking layer BX may be removed at the levels corresponding to the interlayer insulating layers IIL. The blocking layer BX may be separated into a plurality of blocking patterns spaced apart in the Z direction.

Referring to FIGS. 6I and 7I, the tunneling layer TX and a channel layer CH are sequentially formed. The tunneling layer TX and the channel layer CH extend in the Z direction. The tunneling layer TX and the channel layer CH cover the data storage pattern groups CTG. The tunneling layer TX and the channel layer CH cover the protruding patterns PP and the blocking layer BX. The tunneling layer TX extends over the inner surfaces of the blocking layer BX and inner surfaces of the data storage pattern groups CTG. The channel layer CH extends over an inner surface of the tunneling layer TX. The tunneling layer TX and the channel layer CH each have an elliptical column shape in an embodiment. The tunneling layer TX may include an oxide material. The channel layer CH may include polysilicon.

Referring to FIGS. 6J and 7J, a barrier layer BRL and a cover layer CVL are sequentially formed. The barrier layer BRL and the cover layer CVL extend in the Z direction. The barrier layer BRL extends over an inner surface of the channel layer CH. The cover layer CVL extends over an inner surface of the barrier layer BRL. The barrier layer BRL and the cover layer CVL each have an elliptical column shape in an embodiment. The barrier layer BRL and the cover layer CVL cover the channel layer CH. The barrier layer BRL is thinner than the thickness of the channel layer CH and the cover layer CVL. The thickness of the cover layer CVL may vary depending on a location. For example, the cover layer CVL may have a larger thickness along the major axis of the ellipse, in the Y direction, and a smaller thickness along the minor axis of the ellipse in the X direction. The barrier layer BRL may include an oxide material. The cover layer CVL may include polysilicon.

Referring to FIGS. 6K and 7K, a first ring P1 is formed by oxidizing a section of the cover layer CVL. The first ring P1 contacts the inner surface of the barrier layer BRL along the minor axis. Segments of the cover layer CVL that are not oxidized form a first cover pattern CV1 and a second cover pattern CV2. The first cover pattern CV1 is spaced apart from the second cover pattern CV2 in the Y direction.

Referring to FIGS. 6L and 7L, the first ring P1 of the cover layer CVL is removed. The first ring P1 may be removed by a process that selectively etches an oxide material. As the first ring P1 is selectively removed, the cover patterns CV1 and CV2 remain. A section of the barrier layer BRL is exposed along the minor axis. Sections of the barrier layer BRL located along the minor axis in the X direction are exposed.

Referring to FIGS. 6M and 7M, sections of the barrier layer BRL exposed along the minor axis are removed. The first barrier pattern BR1 and the second barrier pattern BR2 are formed by removing the sections of the barrier layer BRL. The first barrier pattern BR1 is spaced apart from the second barrier pattern BR2 in the Y direction. The barrier patterns BR1 and BR2 have a curved shape corresponding to a section of an ellipse.

A section of the channel layer CH exposed along the minor axis are removed. For example, a part of the channel layer CH exposed along the minor axis near an area between the barrier patterns BR1 and BR2 is removed. Sections of the channel layer CH located along the minor axis in the X direction re removed. The first channel pattern CH1 and the second channel pattern CH2 may be formed by removing the sections of the channel layer CH. The first channel pattern CH1 is spaced apart from the second channel pattern CH2 in the Y direction. The channel patterns CH1 and CH2 have curved shapes corresponding to a section of the ellipse.

The channel layer CH may be etched more than the barrier layer BRL. For example, a side surface of the first channel pattern CH1 may be etched farther away from the minor axis than a side surface of the first barrier pattern BR1 is etched. The inner surface of the first channel pattern CH1 may be covered by the first barrier pattern BR1. A section of an outer surface of the first barrier pattern BR1 does not contact the first channel pattern CH1.

The core pillar CO is formed by filling a core material layer between the barrier patterns BR1 and BR2 and between the channel patterns CH1 and CH2. The core pillar CO insulates the first channel pattern CH1 from the second channel pattern CH2. The cell plug CPL includes the protruding patterns PP, the blocking layer BX, the data storage pattern groups CTG, the tunneling layer TX, the channel patterns CH1 and CH2, the barrier patterns BR1 and BR2, and the core pillar CO formed in the channel opening CHO.

Referring to FIGS. 6N and 7N, recesses RC may be formed by removing the sacrificial layers SF. As the sacrificial layers SF are removed, spaces are formed between the interlayer insulating layers IIL. The cell plugs CPL support the interlayer insulating layers IIL that are spaced apart f.

Referring to FIGS. 6O and 7O, the conductive layers CD are formed between the interlayer insulating layers IIL, thereby forming the stack STK. The conductive layers CD fill the recesses RC formed by removing the sacrificial layers SF. The conductive layers CD may include a conductive material.

According to the present disclosure, by using channel openings CHO having an elliptical shape, the level of difficulty of a process of separating the first data storage patterns CT1 from the second data storage patterns CT2 and separating the first channel pattern CH1 from the second channel pattern CH2 may be reduced. By employing a method of removing a section of the data storage layer CT located along the minor axis of the ellipse and removing a section of the channel layer CH located along the minor axis of the ellipse, the integration density of the memory device 100 may be improved while simplifying the process of forming the memory device.

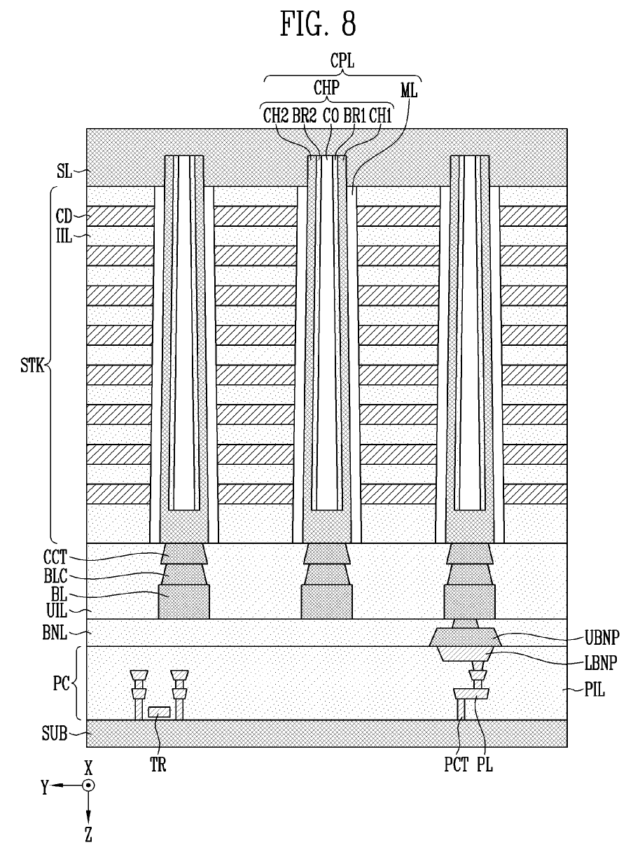

FIG. 8 is cross-sectional diagram of the memory device 100 according to an embodiment of the present disclosure.

According to an embodiment, the memory device 100 includes a wafer bonding structure. In an embodiment, after the cell plugs CPL are formed in the stack STK, an upper insulating layer UIL, cell contacts CCT, bit line contacts BLC, and the bit lines BL are formed. The bit lines BL are connected to the cell plugs CPL via the bit line contacts BLC and the cell contacts CCT. A bonding layer BNL and an upper bonding pad UBNP are formed. The upper bonding pad UBNP is coupled to at least one of the bit lines BL.

The stack STK may be flipped upside down and is bonded to the substrate SUB and the peripheral circuit structure PC over the substrate SUB and the peripheral circuit structure PC. The peripheral circuit structure PC includes transistors TR, peripheral circuit contacts PCT, and peripheral lines PL. The transistors TR, the peripheral circuit contacts PCT, and the peripheral lines PL are located in a peripheral insulating layer PIL. The peripheral circuit contacts PCT and the peripheral lines PL are connected to the cell plugs CPL via a lower bonding pad LBNP.

A sacrificial substrate on the stack STK is removed to expose one end of the cell plugs CPL. During the removal of the sacrificial substrate, memory layers ML of the cell plugs CPL are etched. As a result, the channel pillars CHP are exposed.

The source line SL coupled to the cell plugs CPL is formed. The source line SL contacts the channel patterns CH1 and CH2, the barrier patterns BR1 and BR2, and the core pillar CO. The memory layer ML in FIG. 8 may include the protruding patterns PP, the blocking layer BX, the first data storage patterns CT1, the second data storage patterns CT2, and the tunneling layer TX shown in FIG. 4B.

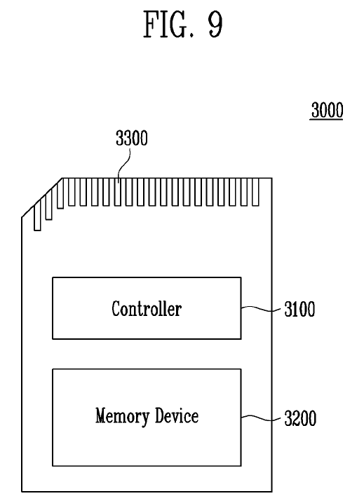

FIG. 9 is a diagram illustrating a memory card system 3000 including a memory device 3200 of the present disclosure.

Referring to FIG. 9, the memory card system 3000 includes a controller 3100, the memory device 3200, and a connector 3300.

The controller 3100 is coupled to the memory device 3200. The controller 3100 is configured to access the memory device 3200. For example, the controller 3100 is configured to control a program operation, a read operation, an erase operation of the memory device 3200, and a background operation. The controller 3100 is configured to provide an interface between the memory device 3200 and a host. The controller 3100 is configured to run or execute firmware to control the memory device 3200. For example, the controller 3100 may include components such as Random-Access Memory (RAM), a processing unit, a host interface, a memory interface, and an error correction circuit.

The controller 3100 communicates with an external device through the connector 3300. The controller 3100 communicates with the external device, such as a host, based on a communication protocol. For example, the controller 3100 is configured to communicate with the external device via at least one of various communication protocols, such as a Universal Serial Bus (USB), a multimedia card (MMC), an embedded MMC (eMMC), Peripheral Component Interconnect (PCI), PCI-express (PCI-E), Advanced Technology Attachment (ATA), Serial-ATA, Parallel-ATA, a Small Computer System Interface (SCSI), an Enhanced Small Disk Interface (ESDI), Integrated Drive Electronics (IDE), Firewire, Universal Flash Storage (UFS), Wi-Fi, Bluetooth, or Non-Volatile Memory express (NVMe). For example, the connector 3300 is configured according at least one of these communication protocols.

The memory device 3200 includes a plurality of memory cells and is configured similarly to the memory device 100 illustrated in FIG. 1, including memory cells configured according to any of FIGS. 4A-4C, 5A-5B, 6A-6O, 7A-7O, and 8.

The controller 3100 and the memory device 3200 may be integrated into a single semiconductor device to form a memory card. For example, the controller 3100 and the memory device 3200 may be integrated into a single semiconductor device to form a memory card such as a Personal Computer Memory Card International Association (PCMCIA), a Compact Flash (CF) card, a smart media card (SM, SMC), a memory stick, a multimedia card (MMC, RS-MMC, MMCmicro, eMMC), an SD card (SD, miniSD, microSD, SDHC), Universal Flash Storage (UFS), and so forth.

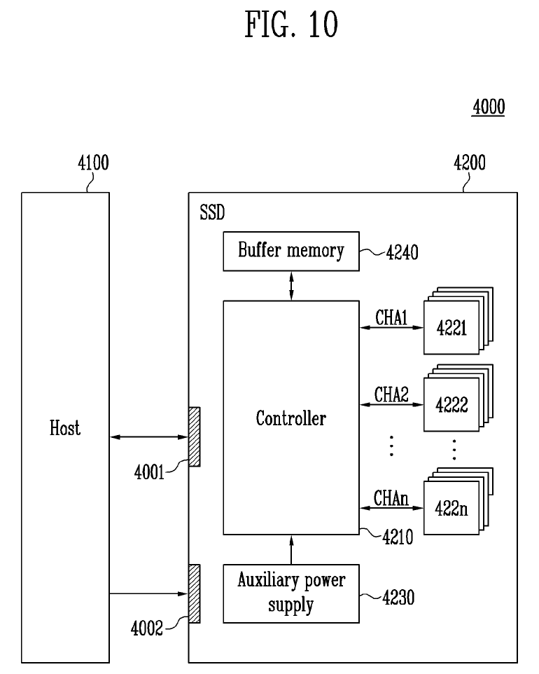

FIG. 10 is a block diagram illustrating a Solid-State Drive (SSD) 4000 system including a memory device of the present disclosure.

Referring to FIG. 10, the SSD system 4000 includes a host 4100 and an SSD 4200. The SSD 4200 exchanges signals with the host 4100 through a signal connector 4001, and the SSD 4200 receives power through a power connector 4002. The SSD 4200 includes a controller 4210, a plurality of memory devices 4221 to 422n, an auxiliary power supply 4230, and buffer memory 4240.

The controller 4210 controls the plurality of memory devices 4221 to 422n in response to signals received from the host 4100. For example, the signals are based on an interface of the host 4100 and the SSD 4200. For example, the signals may be configured according to at least one of various interfaces such as a Universal Serial Bus (USB), a multimedia card (MMC), an embedded MMC (eMMC), Peripheral Component Interconnect (PCI), PCI-express (PCI-E), Advanced Technology Attachment (ATA), Serial-ATA, Parallel-ATA, a Small Computer System Interface (SCSI), an Enhanced Small Disk Interface (ESDI), Integrated Drive Electronics (IDE), Firewire, Universal Flash Storage (UFS), Wi-Fi, Bluetooth, Non-Volatile Memory express (NVMe), and so forth.

The plurality of memory devices 4221 to 422n includes a plurality of memory cells configured to store data. Each of the plurality of memory devices 4221 to 422n is configured similarly to the memory device 100 illustrated in FIG. 1, including memory cells configured according to any of FIGS. 4A-4C, 5A-5B, 6A-6O, 7A-7O, and 8. The plurality of memory devices 4221 to 422n communicates with the controller 4210 through channels CHA1 to CHAn.

The auxiliary power supply 4230 is connected to the host 4100 through a power connector 4002. The auxiliary power supply 4230 receives and is charged with power from the host 4100. The auxiliary power supply 4230 provides power to the SSD 4200 when the power supply from the host 4100 is not reliable or smooth. For example, the auxiliary power supply 4230 may be located in the SSD 4200 or may be located outside the SSD 4200. For example, the auxiliary power supply 4230 is located on a main board and provides auxiliary power to the SSD 4200.

The buffer memory 4240 operates as buffer memory of the SSD 4200. For example, the buffer memory 4240 stores data received from the host 4100 or data received from the plurality of memory devices 4221 to 422n, or the buffer memory 4240 stores metadata, such as, a mapping table, of the memory devices 4221 and 422n. The buffer memory 4240 may include volatile memory, such as DRAM, SDRAM, DDR SDRAM, or LPDDR SDRAM, or non-volatile memory, such as FRAM, ReRAM, STT-MRAM, or PRAM.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a stack including conductive layers alternately stacked with interlayer insulating layers in a first direction, a channel opening extending through the stack in the first direction;
a first channel pattern spaced apart from a second channel pattern in a second direction perpendicular to the first direction, the first channel pattern and the second channel pattern extending in the channel opening in the first direction;
first data storage patterns located between the first channel pattern and the conductive layers and spaced apart in the first direction; and
second data storage patterns located between the second channel pattern and the conductive layers and spaced apart in the first direction;
wherein the first data storage patterns are spaced apart from the second data storage patterns in the second direction.

2. The memory device of claim 1, wherein the channel opening has an elliptical shape with a major axis in the second direction.

3. The memory device of claim 1, further comprising protruding patterns spaced apart in the first direction and located between the first channel pattern and the interlayer insulating layers and between the second channel pattern and the interlayer insulating layers.

4. The memory device of claim 3,
wherein each of the protruding patterns has a first thickness in the second direction and a second thickness in a third direction perpendicular the first direction and the second direction, and
wherein the first thickness is greater than the second thickness.

5. The memory device of claim 3, wherein the first data storage patterns and the second data storage patterns are located between consecutive protruding patterns in the first direction.

6. The memory device of claim 3, wherein each of the protruding patterns surrounds the first channel pattern and the second channel pattern.

7. The memory device of claim 3, wherein the protruding patterns overlap the first data storage patterns and the second data storage patterns in the first direction.

8. The memory device of claim 3, further comprising a blocking layer extending between the protruding patterns and the first data storage patterns and between the protruding patterns and the second data storage patterns.

9. The memory device of claim 8, wherein the blocking layer contacts side surfaces of the conductive layers.

10. The memory device of claim 1, further comprising a tunneling layer extending over outer surfaces of the first channel pattern and the second channel pattern.

11. The memory device of claim 1, further comprising a core pillar located between the first channel pattern and the second channel pattern.

12. The memory device of claim 11, further comprising:
a first barrier pattern located between the first channel pattern and the core pillar; and
a second barrier pattern located between the second channel pattern and the core pillar.

13. The memory device of claim 11, wherein a channel pillar including the first channel pattern, the second channel pattern, and the core pillar has an elliptical column shape having a major axis in the second direction.

14. A memory device comprising:
a stack including conductive layers alternately stacked with interlayer insulating layers in a first direction; and
a cell plug formed within a channel opening extending through the stack in the first direction, wherein the cell plug comprises:
a first channel pattern spaced apart from a second channel pattern in a second direction perpendicular to the first direction;
the first data storage pattern located between consecutive protruding patterns in the first direction; and
the second data storage pattern located between the consecutive protruding patterns in the first direction.
